(19) United States
(12) Patent Application Publication
(10) Pub. No.: US 2025/0240874 A1
(43) Pub. Date: Jul. 24, 2025

(54) MULTILAYER SUBSTRATE AND METHOD FOR MANUFACTURING MULTILAYER SUBSTRATE

(71) Applicant: Murata Manufacturing Co., Ltd., Nagaokakyo-shi (JP)

(72) Inventors: Ryutatsu MIZUKAMI, Nagaokakyo-shi (JP); Takahiro BABA, Nagaokakyo-shi (JP); Tomohiro FURUMURA, Nagaokakyo-shi (JP)

(21) Appl. No.: 19/175,240

(22) Filed: Apr. 10, 2025

Related U.S. Application Data
(63) Continuation of application No. PCT/JP2023/042681, filed on Nov. 29, 2023.

(30) Foreign Application Priority Data
Dec. 14, 2022 (JP) 2022-199648

(51) Int. Cl. H05K 1/02; H05K 1/11; H05K 3/46

(52) U.S. Cl. CPC H05K 1/0237; H05K 1/115; H05K 3/4644; H05K 2201/10242

(57) ABSTRACT

In a multilayer substrate, a first insulating layer includes positive and negative main surfaces. First and second conductive layers are located at the positive main surface. First and second columnar conductors are provided in through-holes in the first insulating layer along a Z axis. An end portion of the first columnar conductor in a positive direction of the Z axis is in contact with the first conductive layer. An end portion of the first columnar conductor in a negative direction of the Z axis is connected to a first conductor of the first columnar conductor. An end portion of the second columnar conductor in the positive direction is in contact with the second conductive layer. An end portion of the second columnar conductor in the negative direction is not in contact with any of the conductors. Materials of the first and second columnar conductors are the same.

### CROSS REFERENCE TO RELATED APPLICATIONS

This application claims the benefit of priority to Japanese Patent Application No. 2022-199648 filed on Dec. 14, 2022 and is a Continuation Application of PCT Application No. PCT/JP2023/042681 filed on Nov. 29, 2023. The entire contents of each application are hereby incorporated herein by reference.

### BACKGROUND OF THE INVENTION

### 1. Field of the Invention

The present invention relates to multilayer substrates each with a structure including multiple laminated insulating layers.

### 2. Description of the Related Art

A method for manufacturing a wiring circuit board described in Japanese Unexamined Patent Application Publication No. 2022-027927 is known as an example of an existing invention relating to a multilayer substrate. This method for manufacturing a wiring circuit board includes overlapping a seed layer and a wiring on a base insulating layer. The seed layer and the wiring are formed from conductors. The electric current path including the seed layer and the wiring thus has reduced resistance.

In the field of the wiring circuit board described in Japanese Unexamined Patent Application Publication No. 2022-027927, the electric current path including a seed layer and a wiring is desired to have reduced resistance.

### SUMMARY OF THE INVENTION

Example embodiments of the present invention provide multilayer substrates and methods for manufacturing multilayer substrates that are each able to reduce resistance of an electric current path.

A multilayer substrate according to an example embodiment of the present invention includes a multilayer body, a first conductive layer, a second conductive layer, a first columnar conductor, a second columnar conductor, and a connection conductor, in which the multilayer body includes a plurality of insulating layers including a first insulating layer laminated along a Z axis, the first insulating layer includes a positive main surface and a negative main surface located in a negative direction of the Z axis from the positive main surface, the first conductive layer and the second conductive layer are provided at the positive main surface of the first insulating layer, the first columnar conductor and the second columnar conductor are located in through-holes extending through the first insulating layer along the Z axis, an end portion of the first columnar conductor in a positive direction of the Z axis is in contact with the first conductive layer, the connection conductor electrically connects conductors to one another in a lamination direction, an end portion of the first columnar conductor in the negative direction of the Z axis is connected to a columnar conductor or a conductive layer with the connection conductor, wherein an end portion of the second columnar conductor in the positive direction of the Z axis is in contact with the second conductive layer, an end portion of the second columnar conductor in the negative direction of the Z axis is not in contact with any of the conductors, and a material of the first columnar conductor and a material of the second columnar conductor are the same.

A method for manufacturing a multilayer substrate according to an example embodiment of the present invention includes a first preparation step, a through-hole forming step, a conductive layer forming step, a columnar conductor forming step, a second preparation step, and a pressure bonding step, in which the first preparation step includes preparing a first insulating layer including a positive main surface and a negative main surface located in a negative direction of a Z axis from the positive main surface and a metal foil covering the positive main surface is covered, the through-hole forming step includes forming a first through-hole and a second through-hole extending through the first insulating layer along the Z axis, the conductive layer forming step includes forming a first conductive layer and a second conductive layer by processing the metal foil, the columnar conductor forming step includes forming a first columnar conductor in the first through-hole and forming a second columnar conductor in the second through-hole, the second preparation step includes preparing a second insulating layer at which a connection conductor is provided, the pressure bonding step includes laminating and pressure bonding a plurality of insulating layers including the first insulating layer and the second insulating layer while locating the first insulating layer in a positive direction of the Z axis from the second insulating layer, an end portion of the first columnar conductor in the positive direction of the Z axis is in contact with the first conductive layer, an end portion of the second columnar conductor in the positive direction of the Z axis is in contact with the second conductive layer, and an end portion of the first columnar conductor in the negative direction of the Z axis is connected to the connection conductor.

With multilayer substrates and methods for manufacturing multilayer substrates according to example embodiments of the present invention, an electric current path achieves reduced resistance.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is an exploded perspective view of a multilayer substrate 10 according to an example embodiment of the present invention.

FIG. 2 is a cross-sectional view of a multilayer substrate 10 according to an example embodiment of the present invention.

FIG. 3 is a cross-sectional view of a multilayer substrate 10 according to an example embodiment of the present invention during manufacture.

FIG. 4 is a cross-sectional view of a multilayer substrate 10 according to an example embodiment of the present invention during manufacture.

FIG. 5 is a cross-sectional view of a multilayer substrate 10 according to an example embodiment of the present invention during manufacture.

FIG. 6 is a cross-sectional view of a multilayer substrate 10 according to an example embodiment of the present invention during manufacture.

FIG. 7 is a cross-sectional view of a multilayer substrate 10 according to an example embodiment of the present invention during manufacture.

FIG. 8 is a cross-sectional view of a multilayer substrate 10 according to an example embodiment of the present invention during manufacture.

FIG. 9 is a cross-sectional view of a multilayer substrate 10 according to an example embodiment of the present invention during manufacture.

FIG. 10 is a cross-sectional view of a multilayer substrate 10 according to an example embodiment of the present invention during manufacture.

FIG. 11 is a cross-sectional view of a multilayer substrate 10a according to an example embodiment of the present invention during manufacture.

FIG. 12 is a cross-sectional view of a multilayer substrate 10b according to an example embodiment of the present invention during manufacture.

FIG. 13 is a top view of an insulating layer 16c of a multilayer substrate 10c according to an example embodiment of the present invention.

FIG. 14 is a top view of an insulating layer 16c of a multilayer substrate 10d according to an example embodiment of the present invention.

FIG. 15 is a rear view of a multilayer substrate 10d according to an example embodiment of the present invention during use.

FIG. 16 is a top view of an insulating layer 16c of a multilayer substrate 10e according to an example embodiment of the present invention.

### DETAILED DESCRIPTION OF THE EXAMPLE EMBODIMENTS

### Example Embodiments

### Structure of Multilayer Substrate

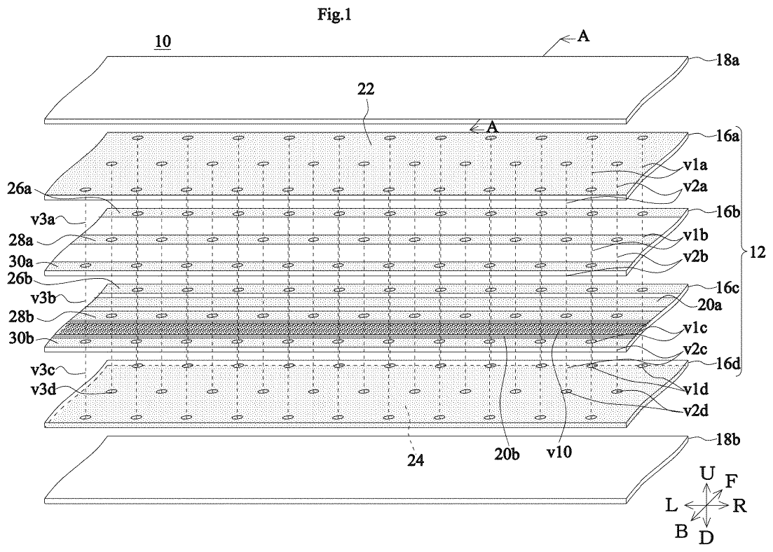

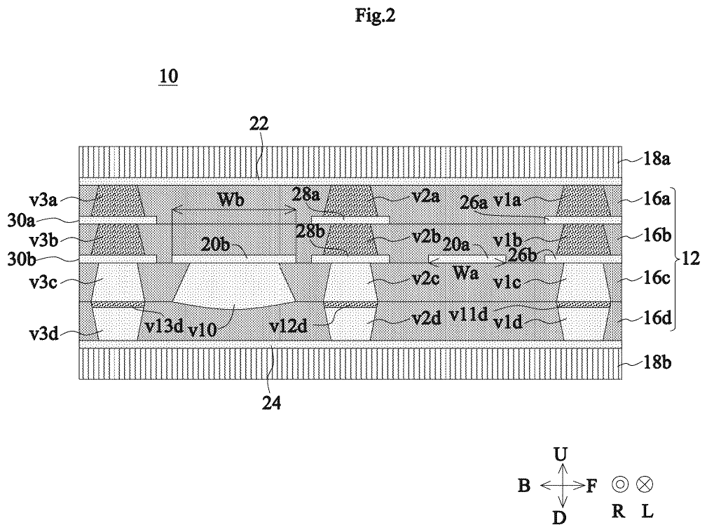

A structure of a multilayer substrate 10 according to an example embodiment of the present invention is described below with reference to the drawings. FIG. 1 is an exploded perspective view of the multilayer substrate 10. FIG. 2 is a cross-sectional view of the multilayer substrate 10. FIG. 2 is a cross-sectional view taken along line A-A in FIG. 1. In FIG. 1, only typical columnar conductors of multiple columnar conductors v1a to v1d, v2a to v2d, and v3a to v3d are denoted with the reference signs.

Herein, directions are defined as described below. A lamination direction of a multilayer body 12 of the multilayer substrate 10 is defined as a vertical direction. The vertical direction is aligned with a Z-axis direction. An upward direction is a positive direction of the Z axis. A downward direction is a negative direction of the Z axis. A direction in which a signal conductor layer 20a and a power-source conductive layer 20b of the multilayer substrate 10 extend is defined as a lateral direction. When viewed in the vertical direction, a width direction of the signal conductor layer 20a and the power-source conductive layer 20b is defined as a front-rear direction. The vertical direction, the front-rear direction, and the lateral direction are orthogonal or substantially orthogonal to one another. The upward direction and the downward direction of the vertical direction may be changed with each other, the leftward direction and the rightward direction of the lateral direction may be changed with each other, or the frontward direction and the rearward direction of the front-rear direction may be changed with each other.

Hereinbelow, X denotes a component or a member of the multilayer substrate 10. Herein, unless otherwise particularly described, portions of X are defined as below. A front portion of X indicates a front half of X. A rear portion of X indicates a rear half of X. A left portion of X indicates a left half of X. A right portion of X indicates a right half of X. An upper portion of X indicates an upper half of X. A lower portion of X indicates a lower half of X. A front end of X indicates an end of X in the front direction. A rear end of X indicates an end of X in the rear direction. A left end of X indicates an end of X in the left direction. A right end of X indicates an end of X in the right direction. An upper end of X indicates an end of X in the upper direction. A lower end of X indicates an end of X in the lower direction. A front end portion of X indicates the front end of X and its periphery. A rear end portion of X indicates the rear end of X and its periphery. A left end portion of X indicates the left end of X and its periphery. A right end portion of X indicates the right end of X and its periphery. An upper end portion of X indicates the upper end of X and its periphery. A lower end portion of X indicates the lower end of X and its periphery.

First, with reference to FIG. 1, a structure of the multilayer substrate 10 is described. The multilayer substrate 10 transmits high-frequency signals. The multilayer substrate 10 is used in an electronic device, such as, for example, a smartphone, to electrically connect two circuits. As illustrated in FIG. 1, the multilayer substrate 10 includes the multilayer body 12, protective layers 18a and 18b, the signal conductor layer 20a, the power-source conductive layer 20b, a first ground conductive layer 22, a second ground conductive layer 24, ground conductive layers 26a, 26b, 28a, 28b, 30a, and 30b, multiple columnar conductors v1a to v1d, multiple columnar conductors v2a to v2d, multiple columnar conductors v3a to v3d, a columnar conductor v10, and connection conductors v11d, v12d, and v13d. The connection conductors v11d, v12d, and v13d are made from a different material from a material of the columnar conductors v1c to v3c and v1d to v3d.

The multilayer body 12 has a plate shape. The multilayer body 12 thus includes an upper main surface (a positive main surface), and a lower main surface (a negative main surface) located below (in a negative direction of the Z axis from) the upper main surface (the positive main surface). The upper main surface and the lower main surface of the multilayer body 12 have a rectangular or substantially rectangular shape including long sides extending along a lateral axis. The dimension of the multilayer body 12 in the lateral direction is thus longer than the dimension of the multilayer body 12 in the front-rear direction. The multilayer body 12 has flexibility.

As illustrated in FIG. 1, the multilayer body 12 includes insulating layers 16a to 16d including an insulating layer 16c (a first insulating layer) that are laminated along a vertical axis (the Z axis). The insulating layers 16a to 16d are arranged in this order from the top to the bottom. The insulating layers 16a to 16d each include an upper main surface (a positive main surface) and a lower main surface (a negative main surface) located below (in the negative direction of the Z axis from) the upper main surface (the positive main surface). The material of the insulating layers 16a to 16d is, for example, thermoplastic resin. Examples of thermoplastic resin include a liquid crystal polymer. The insulating layers 16a to 16d fuse with one another adjacent to each other vertically.

High-frequency signals are transmitted to the signal conductor layer 20a. As illustrated in FIG. 1, the signal conductor layer 20a (a third conductive layer) is located at the upper main surface (the positive main surface) of the insulating layer 16c (the first insulating layer). The signal conductor layer 20a has a linear shape extending in the lateral axis when viewed in the downward direction. The signal conductor layer 20a includes an upper main surface and a lower main surface located below the upper main surface. The surface roughness of the lower main surface of the signal conductor layer 20a is greater than the surface roughness of the upper main surface of the signal conductor layer 20a.

The power-source potential is connected to the power-source conductive layer 20b. As illustrated in FIG. 1, the power-source conductive layer 20b (the second conductive layer) is located at the upper main surface (the positive main surface) of the insulating layer 16c (the first insulating layer). The power-source conductive layer 20b has a linear shape extending along the lateral axis when viewed in the downward direction (in the negative direction of the Z axis). Thus, the power-source conductive layer 20b is parallel or substantially parallel to the signal conductor layer 20a. In the present example embodiment, the power-source conductive layer 20b is located at the rear of the signal conductor layer 20a. As illustrated in FIG. 2, a width Wb of the power-source conductive layer 20b is larger than a width Wa of the signal conductor layer 20a. The power-source conductive layer 20b (the second conductive layer) includes an upper main surface (a positive main surface) and a lower main surface (a negative main surface) located below (in the negative direction of the Z axis from) the upper main surface (the positive main surface). The surface roughness of the lower main surface (the negative main surface) of the power-source conductive layer 20b is greater than the surface roughness of the upper main surface (the positive main surface) of the power-source conductive layer 20b.

As illustrated in FIG. 1, the first ground conductive layer 22 is disposed at the multilayer body 12. The first ground conductive layer 22 is located above the signal conductor layer 20a and the power-source conductive layer 20b, and, when viewed in the downward direction, overlaps the signal conductor layer 20a and the power-source conductive layer 20b. In the present example embodiment, the first ground conductive layer 22 is located at the upper main surface of the insulating layer 16a. The first ground conductive layer 22 covers the entirety or substantially the entirety of the upper main surface of the insulating layer 16a. The first ground conductive layer 22 includes an upper main surface and a lower main surface located below the upper main surface. The surface roughness of the lower main surface of the first ground conductive layer 22 is greater than the surface roughness of the upper main surface of the first ground conductive layer 22. The ground potential is connected to the first ground conductive layer 22.

As illustrated in FIG. 1, the second ground conductive layer 24 is disposed at the multilayer body 12. The second ground conductive layer 24 is located below the signal conductor layer 20a and the power-source conductive layer 20b, and, when viewed in the downward direction, overlaps the signal conductor layer 20a and the power-source conductive layer 20b. In the present example embodiment, the second ground conductive layer 24 is located at the lower main surface of the insulating layer 16d. The second ground conductive layer 24 covers the entirety or substantially the entirety of the lower main surface of the insulating layer 16d. The second ground conductive layer 24 includes an upper main surface and a lower main surface located below the upper main surface. The surface roughness of the upper main surface of the second ground conductive layer 24 is greater than the surface roughness of the lower main surface of the second ground conductive layer 24. The ground potential is connected to the second ground conductive layer 24. The signal conductor layer 20a, the first ground conductive layer 22, and the second ground conductive layer 24 described above have a strip line structure.

As illustrated in FIG. 1, the ground conductive layers 26a, 28a, and 30a are disposed at the multilayer body 12. When viewed in the downward direction, the ground conductive layers 26a, 28a, and 30a do not overlap the signal conductor layer 20a and the power-source conductive layer 20b. In the present example embodiment, the ground conductive layers 26a, 28a, and 30a are located at the upper main surface of the insulating layer 16b. The ground conductive layers 26a, 28a, and 30a have a linear shape extending in the lateral direction when viewed in the downward direction. The ground conductive layer 26a is located in front of the signal conductor layer 20a when viewed in the downward direction. The ground conductive layer 28a is located at the rear of the signal conductor layer 20a and in front of the power-source conductive layer 20b when viewed in the downward direction. The ground conductive layer 30a is located at the rear of the power-source conductive layer 20b when viewed in the downward direction. The ground conductive layers 26a, 28a, and 30a each include an upper main surface and a lower main surface located below the upper main surface. The surface roughness of the lower main surface of each of the ground conductive layers 26a, 28a, and 30a is greater than the surface roughness of the upper main surface of the ground conductive layer 26a, 28a, or 30a.

As illustrated in FIG. 1, the ground conductive layers 26b, 28b, and 30b are disposed at the multilayer body 12. When viewed in the downward direction, the ground conductive layers 26b, 28b, and 30b do not overlap the signal conductor layer 20a and the power-source conductive layer 20b. In the present example embodiment, the ground conductive layers 26b, 28b, and 30b (first conductive layers) are located at the upper main surface of the insulating layer 16c. The ground conductive layers 26b, 28b, and 30b each have a linear shape extending in the lateral direction when viewed in the downward direction. The ground conductive layer 26b is located in front of the signal conductor layer 20a when viewed in the downward direction. The ground conductive layer 28b is located at the rear of the signal conductor layer 20a and in front of the power-source conductive layer 20b when viewed in the downward direction. The ground conductive layer 30b is located at the rear of the power-source conductive layer 20b when viewed in the downward direction. The ground conductive layers 26b, 28b, and 30b each include an upper main surface and a lower main surface located below the upper main surface. The surface roughness of the lower main surface of each of the ground conductive layers 26b, 28b, and 30b is greater than the surface roughness of the upper main surface of the ground conductive layer 26b, 28b, or 30b.

As illustrated in FIG. 2, the multiple columnar conductors v1a, v2a, and v3a extend through the insulating layer 16a along the vertical axis. The multiple columnar conductors v1a, v2a, and v3a each include a section in which its thickness decreases further as it extends farther in the upward direction. The upper end portions of the multiple columnar conductors v1a are in contact with the first ground conductive layer 22. The lower end portions of the multiple columnar conductors v1a are in contact with the ground conductive layer 26a. The multiple columnar conductors v1a are arranged in a line along the lateral axis. The upper end portions of the multiple columnar conductors v2a are in contact with the first ground conductive layer 22. The lower end portions of the multiple columnar conductors v2a are in contact with the ground conductive layer 28a. The multiple columnar conductors v2a are arranged in a line along the lateral axis. The upper end portions of the multiple columnar conductors v3a are in contact with the first ground conductive layer 22. The lower end portions of the multiple columnar conductors v3a are in contact with the ground conductive layer 30a. The multiple columnar conductors v3a are arranged in a line along the lateral axis.

Multiple columnar conductors v1b, v2b, and v3b extend through the insulating layer 16b along the vertical axis. The multiple columnar conductors v1b, v2b, and v3b each include a section in which its thickness decreases further as it extends farther in the upward direction. The upper end portions of the multiple columnar conductors v1b are in contact with the ground conductive layer 26a. The lower end portions of the multiple columnar conductors v1b are in contact with the ground conductive layer 26b. The multiple columnar conductors v1b are arranged in a line along the lateral axis. The upper end portions of the multiple columnar conductors v2b are in contact with the ground conductive layer 28a. The lower end portions of the multiple columnar conductors v2b are in contact with the ground conductive layer 28b. The multiple columnar conductors v2b are arranged in a line along the lateral axis. The upper end portions of the multiple columnar conductors v3b are in contact with the ground conductive layer 30a. The lower end portions of the multiple columnar conductors v3b are in contact with the ground conductive layer 30b. The multiple columnar conductors v3b are arranged in a line along the lateral axis.

Multiple columnar conductors v1c, v2c, and v3c (first columnar conductors) are disposed in through-holes extending through the insulating layer 16c (the first insulating layer) along the vertical axis. In the present example embodiment, the multiple columnar conductors v1c, v2c, and v3c (the first columnar conductors) extend through the insulating layer 16c (the first insulating layer) along the vertical axis. The multiple columnar conductors v1c, v2c, and v3c (the first columnar conductors) each include a section in which its thickness decreases further as it extends farther in the upward direction (the positive direction of the Z axis). The upper end portions of the multiple columnar conductors v1c are in contact with the ground conductive layer 26b. The multiple columnar conductors v1c are arranged in a line along the lateral axis. The upper end portions (the first columnar conductors) of the multiple columnar conductors v2c are in contact with the ground conductive layer 28b. The multiple columnar conductors v2c are arranged in a line along the lateral axis. The upper end portions of the multiple columnar conductors v3c are in contact with the ground conductive layer 30b. The multiple columnar conductors v3c are arranged in a line along the lateral axis.

Multiple columnar conductors v1d, v2d, and v3d are disposed in through-holes extending through the insulating layer 16d along the vertical axis. The upper ends of the multiple columnar conductors v1d, the upper ends of the multiple columnar conductors v2d, and the upper ends of the multiple columnar conductors v3d are located below the upper main surface of the insulating layer 16d. The multiple columnar conductors v1d, v2d, and v3d each include a section in which its thickness decreases further as it extends farther in the downward direction. The lower end portions of the multiple columnar conductors v1d are in contact with the second ground conductive layer 24. The multiple columnar conductors v1d are arranged in a line along the lateral axis. The lower end portions of the multiple columnar conductors v2d are in contact with the second ground conductive layer 24. The multiple columnar conductors v2d are arranged in a line along the lateral axis. The lower end portions of the multiple columnar conductors v3d are in contact with the second ground conductive layer 24. The multiple columnar conductors v3d are arranged in a line along the lateral axis.

Multiple connection conductors v11d, v12d, and v13d are disposed in through-holes extending through the insulating layer 16d along the vertical axis. In the present example embodiment, the multiple connection conductors v11d, v12d, and v13d are respectively located above the multiple columnar conductors v1d, v2d, and v3d. Thus, the lower end portions of the multiple columnar conductors v1c are in contact with multiple connection conductors v11d. The upper end portions of the multiple columnar conductors v1d are in contact with the multiple connection conductors v11d. Thus, the lower end portions of the multiple columnar conductors v1c are connected to the multiple columnar conductors v1d located below the multiple connection conductors 11c with the multiple connection conductors v11d interposed therebetween. The lower end portions of the multiple columnar conductors v2c are in contact with the multiple connection conductors v12d. The upper end portions of the multiple columnar conductors v2d are in contact with the multiple connection conductors v12d. Thus, the lower end portions of the multiple columnar conductors v2c (the first columnar conductors) are connected to the multiple columnar conductors v2d located below (in the negative direction of the Z axis from) the multiple columnar conductors v2c (the first columnar conductors) with the multiple connection conductors v12d interposed therebetween. The lower end portions of the multiple columnar conductors v3c are in contact with the multiple connection conductors v13d. The upper end portions of the multiple columnar conductors v3d are in contact with the multiple connection conductors v13d. The lower end portions of the multiple columnar conductors v3c are thus connected to the multiple columnar conductors v3d located below the multiple columnar conductors v3c with the multiple connection conductors v13d interposed therebetween.

The columnar conductor v10 (the second columnar conductor) extends through the insulating layer 16c (the first insulating layer) along the vertical axis. The columnar conductor v10 (the second columnar conductor) includes a section in which its thickness decreases further as it extends farther in the upward direction (the positive direction of the Z axis). The upper end portion (an end portion in the positive direction of the Z axis) of the columnar conductor v10 (the second columnar conductor) is in contact with the power-source conductive layer 20b (the second conductive layer). The lower end portion (an end portion in the negative direction of the Z axis) of the columnar conductor v10 (the second columnar conductor) is not in contact any conductor. The end surface of the columnar conductor v10 (the second columnar conductor) facing downward (in the negative direction of the Z axis) protrudes in the downward direction (in the negative direction of the Z axis). The columnar conductor v10 has a linear shape extending along the lateral axis when viewed in the downward direction. The columnar conductor v10 extends along the power-source conductive layer 20b.

The upper end portion (an end portion in the positive direction of the Z axis) of the columnar conductor (a fourth columnar conductor) having the following structure is not connected to the signal conductor layer 20a (the third conductive layer). The columnar conductor (the fourth columnar conductor) extends through the insulating layer 16c (the first insulating layer) along the vertical axis (the Z axis). The lower end portion (an end portion in the negative direction of the Z axis) of the columnar conductor (the fourth columnar conductor) is not in contact with any conductor. However, an inter-layer conductor electrically connected to an outer electrode may be connected to the signal conductor layer 20a.

The protective layer 18a covers the upper main surface of the multilayer body 12. The protective layer 18a thus protects the first ground conductive layer 22. The protective layer 18b covers the lower main surface of the multilayer body 12. The protective layer 18b thus protects the second ground conductive layer 24. The material of the protective layers 18a and 18b described above is different from the material of the insulating layers 16a to 16d. An example of the protective layers 18a and 18b is a solder resist. The material of solder resist is, for example, a composite of a blend of alkali soluble resin, a photopolymerization initiator, an epoxy resin to improve thermal resistance, and an inorganic powder.

The signal conductor layer 20a, the power-source conductive layer 20b, the first ground conductive layer 22, the second ground conductive layer 24, and the ground conductive layers 26a, 26b, 28a, 28b, 30a, and 30b are formed by, for example, etching a metal foil disposed on the upper main surface or the lower main surface of each of the insulating layers 16a to 16d. The metal foil is, for example, a copper foil. As described above, the material of the signal conductor layer 20a, the material of the power-source conductive layer 20b, the material of the first ground conductive layer 22, the material of the second ground conductive layer 24, and the materials of the ground conductive layers 26a, 26b, 28a, 28b, 30a, and 30b (the material of the first conductive layers and the material of the second conductive layers) are metals not including resin.

For example, the multiple columnar conductors v1a and v1b, the multiple columnar conductors v2a and v2b, and the multiple columnar conductors v3a and v3b are via-hole conductors. The via-hole conductors are manufactured by forming through-holes in the insulating layers 16a and 16b, filling the through-holes with a conductive paste, and sintering the conductive paste. The material of the multiple columnar conductors v1a and v1b, the multiple columnar conductors v2a and v2b, and the multiple columnar conductors v3a and v3b includes a mixture of a resin and a metal.

The multiple columnar conductors v1c and v1d, the multiple columnar conductors v2c and v2d, the multiple columnar conductors v3c and v3d, and the columnar conductor v10 are, for example, through-hole conductors. The through-hole conductors are formed by forming through-holes in the insulating layers 16c and 16d, and metal plating the through-holes. The material of the multiple columnar conductors v1c and v1d, the material of the multiple columnar conductors v2c and v2d, the material of the multiple columnar conductors v3c and v3d, and the material of the columnar conductor v10 are a metal. An example of the metal is copper. As described above, the material of the multiple columnar conductors v1c and v1d, the material of the multiple columnar conductors v2c and v2d, the material of the multiple columnar conductors v3c and v3d (the material of the first columnar conductor), and the material of the columnar conductor v10 (the material of the second columnar conductor) are a metal not including a resin. The material of the signal conductor layer 20a, the material of the power-source conductive layer 20b, the material of the first ground conductive layer 22, the material of the second ground conductive layer 24, the material of the ground conductive layers 26a, 26b, 28a, 28b, 30a, and 30b, the material of the multiple columnar conductors v1c and v1d, the material of the multiple columnar conductors v2c and v2d, and the material of the multiple columnar conductors v3c and v3d (the material of the first conductive layer, the material of the second conductive layer, the material of the first columnar conductor, and the material of the second columnar conductor) are the same.

The multiple connection conductors v11d, v12d, and v13d are manufactured by filling the through-holes in which the multiple columnar conductors v1d, v2d, and v3d are formed with a conductive paste and sintering the conductive paste.

The multiple connection conductors v11d, v12d, and v13d include a mixture of a resin and a metal. These connection conductors v11d, v12d, and v13d may be, for example, an alloyed metal such as solder.

### Method for Manufacturing Multilayer Substrate 10

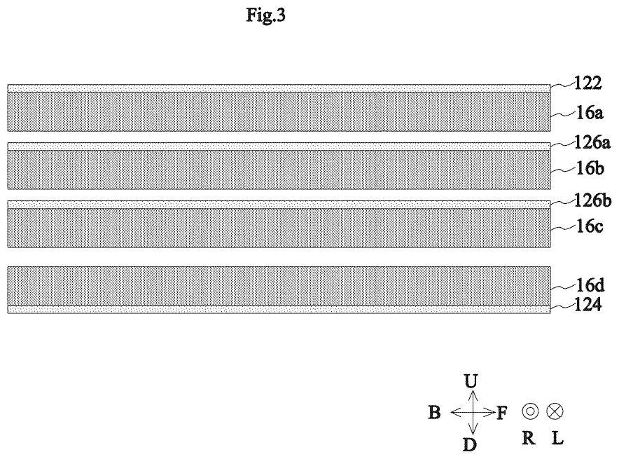

Subsequently, an example of a method for manufacturing the multilayer substrate 10 according to an example embodiment of the present invention is described with reference to the drawings. FIGS. 3 to 10 are cross-sectional views during manufacture of the multilayer substrate 10.

First, as illustrated in FIG. 3, the insulating layers 16a to 16c (the first insulating layers) at which metal foil 122, 126a, and 126b is disposed to cover the upper main surfaces (the positive main surfaces) of the insulating layers 16a to 16c (the first insulating layers) are prepared (a first preparation step). The insulating layer 16d at which metal foil 124 is disposed to cover the lower main surface of the insulating layer 16d is prepared.

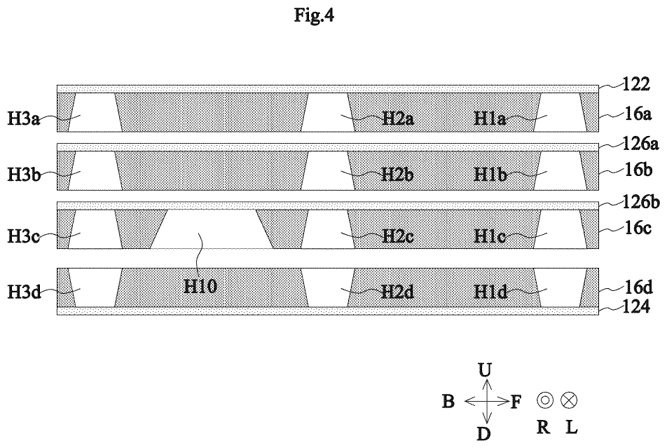

As illustrated in FIG. 4, for example, light beams are then emitted from below the insulating layer 16a to form through-holes H1a, H2a, and H3a extending through the insulating layer 16a along the vertical axis (the Z axis). In addition, light beams are emitted from below the insulating layer 16b to form through-holes H1b, H2b, and H3b extending through the insulating layer 16b along the vertical axis (the Z axis). In addition, light beams are emitted from below the insulating layer 16c to form through-holes H1c, H2c, and H3c (the first through-holes) and a second through-hole H10 extending through the insulating layer 16c (the first insulating layer) along the vertical axis (the Z axis) (a through-hole forming step). In addition, light beams are emitted from above the insulating layer 16d to form through-holes H1d, H2d, and H3d extending through the insulating layer 16d along the vertical axis (the Z axis). In the through-hole forming step, the through-holes H1a, H2a, H3a, H1b, H2b, H3b, H1c, H2c, H3c, H1d, H2d, and H3d (the first through-holes) and the second through-hole H10 may be formed by, for example, wet-etching instead of beam emission.

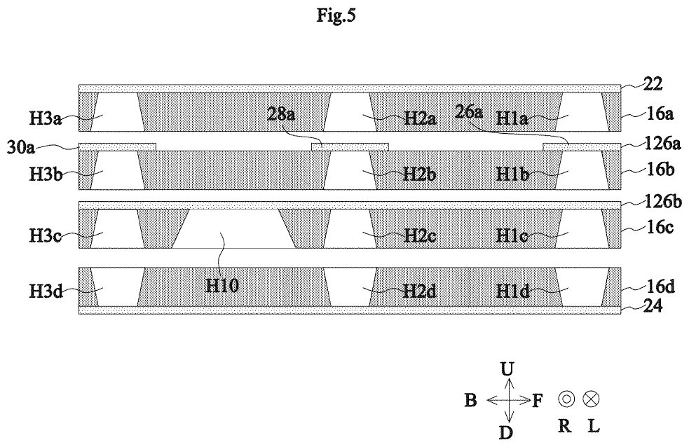

As illustrated in FIG. 5, the metal foil 122 and 126a is then processed to form the first ground conductive layer 22 and the ground conductive layers 26a, 28a, and 30a (a conductive layer forming step). In the conductive layer forming step, the first ground conductive layer 22 and the ground conductive layers 26a, 28a, and 30a are formed by etching the metal foil 122 and 126a using masks.

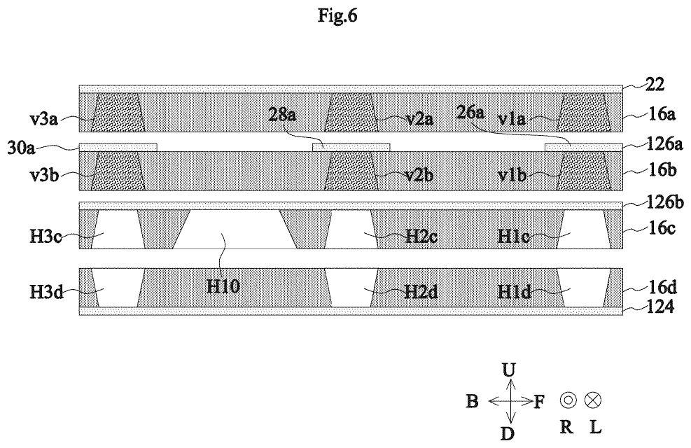

As illustrated in FIG. 6, the through-holes H1a, H2a, H3a, H1b, H2b, and H3b are then filled with the conductive paste.

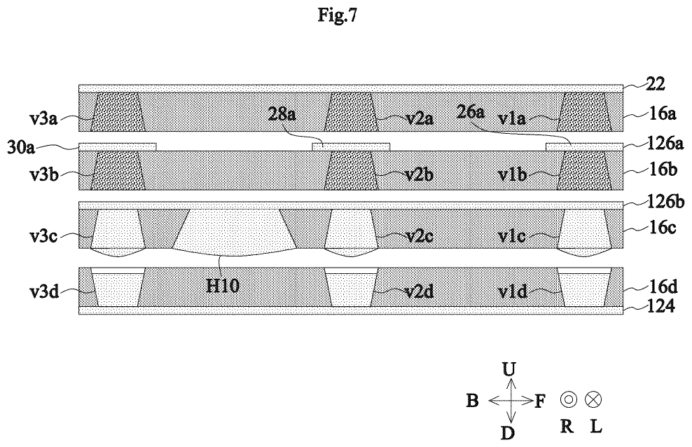

As illustrated in FIG. 7, the columnar conductors v1c, v2c, v3c, v1d, v2d, and v3d and the columnar conductor v10 (the first columnar conductor and the second columnar conductor) are then respectively formed in the through-holes H1c, H2c, H3c, H1d, H2d, and H3d (the first through-holes) and the second through-hole H10 (a columnar conductor forming step) from the same material as the metal foil 126b and 124. In the columnar conductor forming step, the insulating layer 16d (the second insulating layer) at which the columnar conductor v2d (the first conductor) is disposed is prepared (the second preparation step).

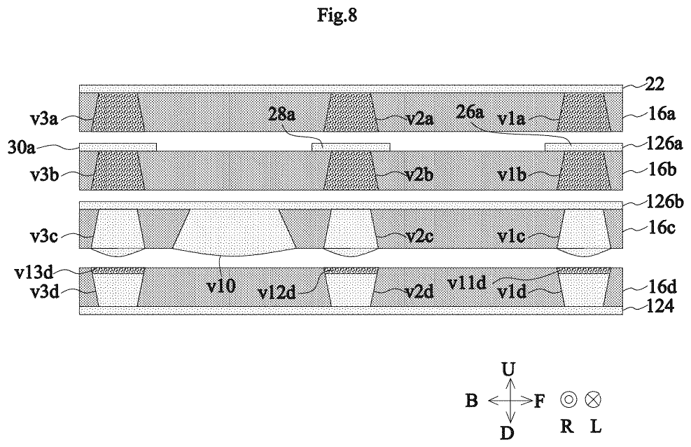

As illustrated in FIG. 8, a conductive paste is then applied onto the columnar conductors v1d, v2d, and v3d.

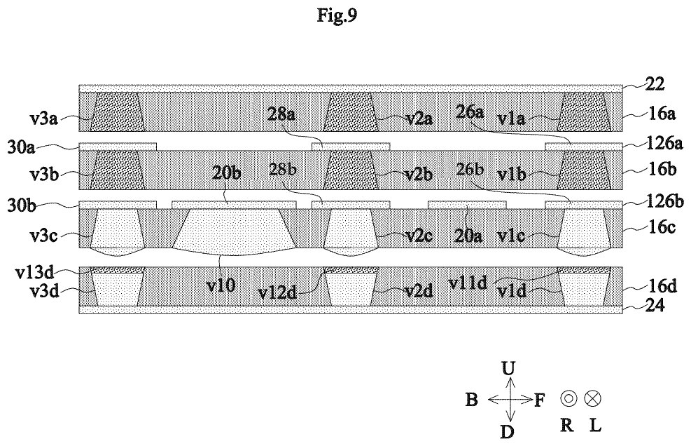

As illustrated in FIG. 9, the metal foil 126b and 124 is then processed to form the second ground conductive layer 24, and the ground conductive layers 26b, 28b, and 30b (a conductive layer forming step). In the conductive layer forming step, the second ground conductive layer 24 and the ground conductive layers 26b, 28b, and 30b are formed by etching the metal foil 126b and 124 using masks.

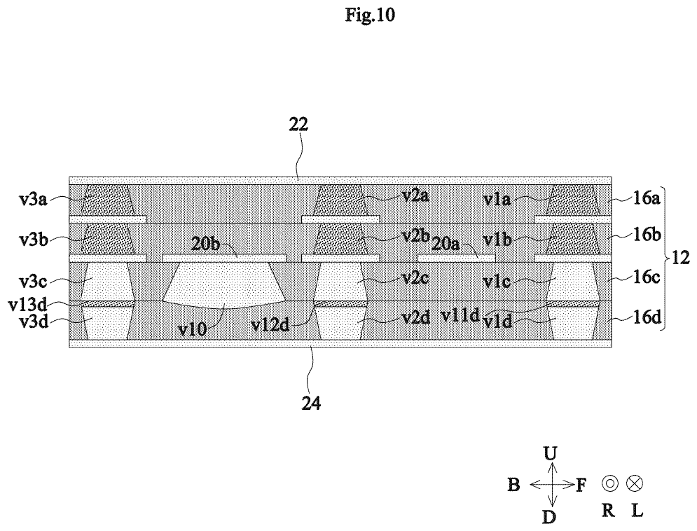

As illustrated in FIG. 10, the insulating layers 16a to 16d including the insulating layer 16c (the first insulating layer) and the insulating layer 16d (the second insulating layer) are then laminated and pressure bonded while allowing the insulating layer 16c (the first insulating layer) to be located above (in the positive direction of the Z axis) the insulating layer 16d (the second insulating layer) (pressure bonding step). The pressure bonding step includes a heating process and a pressing process.

As illustrated in FIG. 2, the protective layers 18a and 18b are formed at the pressure-bonded multilayer body 12. With the above steps, the multilayer substrate 10 is completed.

### Advantageous Effects

In the multilayer substrate 10, the upper end portion of the columnar conductor v10 is in contact with the power-source conductive layer 20b. Thus, the cross-sectional area of the electric current path increases. This structure can thus reduce resistance of the electric current path including the power-source conductive layer 20b and the columnar conductor v10. Particularly, a large electric current flows through the power-source conductive layer 20b. Thus, a reduction of the resistance of the power-source conductive layer 20b effectively reduces or prevents the power loss of the multilayer substrate 10.

The multilayer substrate 10 does not require an addition of a new process of forming the columnar conductor v10. More specifically, the columnar conductors v1c, v2c, and v3c and the columnar conductor v10 are disposed in the through-holes extending through the insulating layer 16c along the vertical axis. Thus, the columnar conductor v10 can be formed in the process of forming the columnar conductors v1c, v2c, and v3c. Thus, the multilayer substrate 10 does not require an addition of a new process of forming the columnar conductor v10.

The surface roughness of the lower main surface of the power-source conductive layer 20b is greater than the surface roughness of the upper main surface of the power-source conductive layer 20b. However, the columnar conductor v10 is in contact with the lower main surface of the power-source conductive layer 20b. Thus, the area of the surface of the power-source conductive layer 20b with higher surface roughness is reduced. Thus, the electric current path including the power-source conductive layer 20b and the columnar conductor v10 has reduced resistance.

The material of the columnar conductor v10 (the material of the second columnar conductor) is a metal not including a resin. Thus, the columnar conductor v10 has low resistance. The electric current path including the power-source conductive layer 20b and the columnar conductor v10 can thus have reduced resistance.

The columnar conductor v10 (the second columnar conductor) includes a section in which its thickness decreases further as it extends farther in the upward direction (the positive direction of the Z axis). More specifically, the columnar conductor v10 has a tapered shape. Thus, the electric current path including the power-source conductive layer 20b and the columnar conductor v10 can have reduced resistance for the following reason. More specifically, the width of the upper end of the columnar conductor v10 in the direction along the lateral axis is smaller than the width of the power-source conductive layer 20b in the direction along the lateral axis. This structure is made to prevent the columnar conductor v10 from being displaced out of the power-source conductive layer 20b. The width of the lower end of the columnar conductor v10 in the direction along the lateral axis is not restricted by the width of the power-source conductive layer 20b in the direction along the lateral axis. Thus, the width of the lower end of the columnar conductor v10 in the direction along the lateral axis may be larger than the width of the upper end of the columnar conductor v10 in the direction along the lateral axis. The volume of the columnar conductor v10 is thus larger than the volume of a columnar conductor having a uniform thickness. The electric current path including the power-source conductive layer 20b and the columnar conductor v10 can thus have reduced resistance.

The lower end surface of the columnar conductor v10 protrudes in the downward direction. Thus, the volume of the columnar conductor v10 is increased, and the electric current path including the power-source conductive layer 20b and the columnar conductor v10 can have reduced resistance.

### First Modified Example

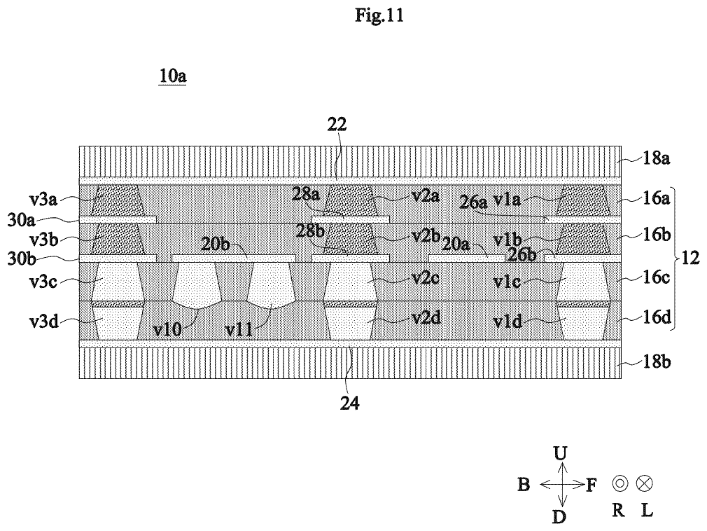

A multilayer substrate 10a according to a first modified example embodiment of the present invention is described below with reference to the drawings. FIG. 11 is a cross-sectional view of the multilayer substrate 10a.

The multilayer substrate 10a differs from the multilayer substrate 10 in that it further includes a columnar conductor v11 (a third columnar conductor). The upper end portion (the end portion in the positive direction of the Z axis) of the columnar conductor v11 (the third columnar conductor) is in contact with the power-source conductive layer 20b (the second conductive layer). The lower end portion (the end portion in the negative direction of the Z axis) of the columnar conductor v11 (the third columnar conductor) is not in contact with any conductor. When viewed in the downward direction (in the negative direction of the Z axis), the columnar conductor v10 (the second columnar conductor) and the columnar conductor v11 (the third columnar conductor) are arranged in the width direction of the power-source conductive layer 20b (the second conductive layer). The material of the columnar conductor v11 is the same as the material of the columnar conductor v10. Other components of the multilayer substrate 10a are the same or substantially the same as those of the multilayer substrate 10, and thus are not described. The multilayer substrate 10a can achieve the same or substantially the same advantageous effects as the multilayer substrate 10.

The multilayer substrate 10a further includes the columnar conductor v11, and thus has an increased surface area of a conductor connected to the power-source conductive layer 20b. The multilayer substrate 10a thus has high heat dissipation properties.

### Second Modified Example

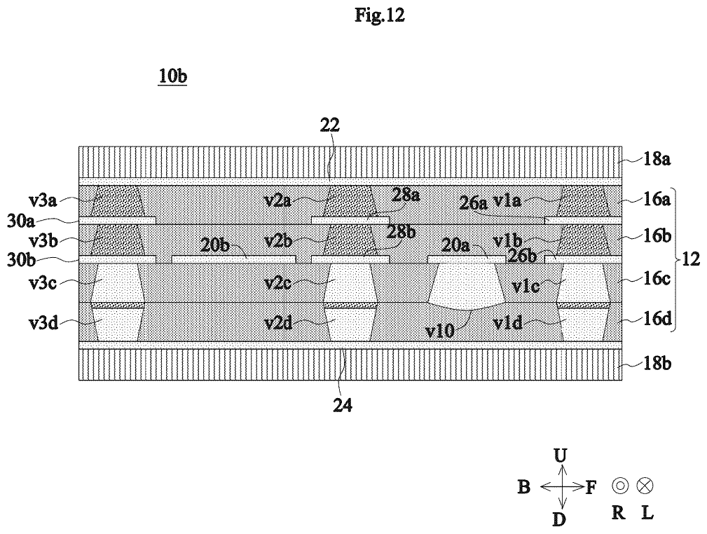

A multilayer substrate 10b according to a second modified example embodiment of the present invention is described below with reference to the drawings. FIG. 12 is a cross-sectional view of the multilayer substrate 10b.

The multilayer substrate 10b differs from the multilayer substrate 10 in that the signal conductor layer 20a defines and functions as a second conductive layer. The upper end portion of the columnar conductor v10 is thus in contact with the signal conductor layer 20a. High-frequency signals with frequencies higher than or equal to about 20 GHz are transmitted to the signal conductor layer 20a (the second conductive layer). Other components of the multilayer substrate 10b are the same or substantially the same as those of the multilayer substrate 10, and thus are not described. The multilayer substrate 10b can achieve the same or substantially the same advantageous effects as the multilayer substrate 10.

The multilayer substrate 10b has a reduced transmission loss of the signal conductor layer 20a. More specifically, high-frequency signals flow near the surface of the signal conductor layer 20a due to the skin effect. The signal conductor layer 20a thus preferably has low surface roughness. The surface roughness of the lower main surface of the signal conductor layer 20a is thus greater than the surface roughness of the upper main surface of the signal conductor layer 20a. The columnar conductor v10 is in contact with the lower main surface of the signal conductor layer 20a. Thus, the surface of the signal conductor layer 20a with high surface roughness is reduced. The transmission loss of the signal conductor layer 20a is thus reduced.

### Third Modified Example

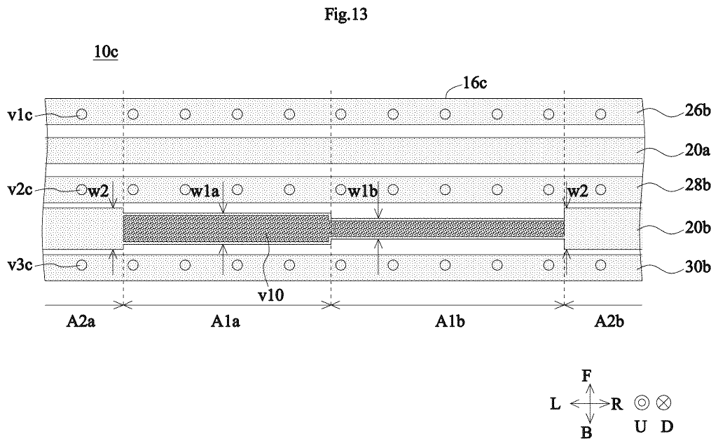

A multilayer substrate 10c according to a third modified example embodiment of the present invention is described below with reference to the drawings. FIG. 13 is a top view of an insulating layer 16c of the multilayer substrate 10c.

The multilayer substrate 10c differs from the multilayer substrate 10 in the shape of the power-source conductive layer 20b and the shape of the columnar conductor v10. More specifically, the multilayer substrate 10c includes first sections Ala and Alb in which the power-source conductive layer 20b (the second conductive layer) has first widths w1a and w1b, and includes second sections A2a and A2b in which the power-source conductive layer 20b (the second conductive layer) has a second width w2 larger than the first width w1a, w1b. The first width w1a is larger than the first width w1b. The second width w2 is the largest width of the power-source conductive layer 20b (the second conductive layer). The columnar conductor v10 is disposed in the first sections Ala and Alb. The columnar conductor v10 (the second columnar conductor) is not disposed in the second sections A2a and A2b. Other components of the multilayer substrate 10c are the same or substantially the same as those of the multilayer substrate 10, and thus are not described. The multilayer substrate 10c can achieve the same or substantially the same advantageous effects as the multilayer substrate 10.

In the multilayer substrate 10c, the power-source conductive layer 20b is more likely to have increased resistance in the first sections Ala and Alb. Thus, the columnar conductor v10 is disposed in the first sections Ala and Alb. Therefore, in the multilayer substrate 10c, the electric current path including the power-source conductive layer 20b and the columnar conductor v10 can have reduced resistance.

### Fourth Modified Example

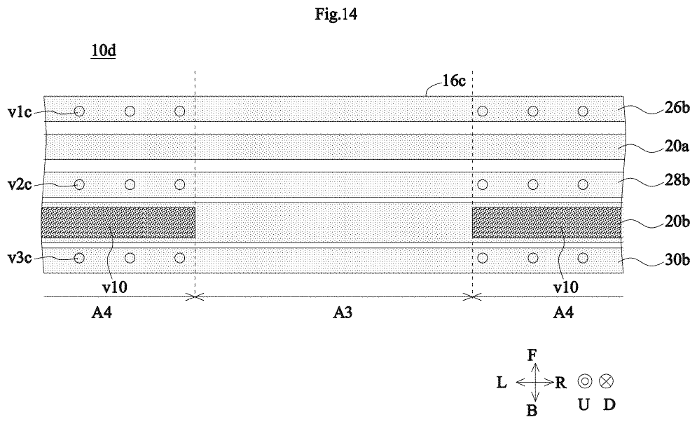

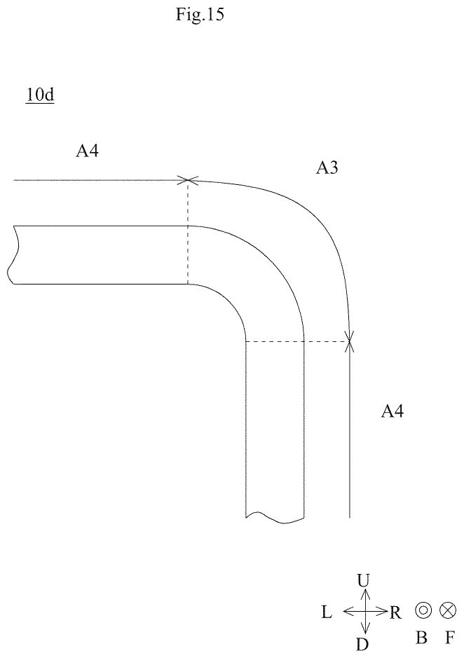

A multilayer substrate 10d according to a fourth modified example embodiment of the present invention is described below with reference to the drawings. FIG. 14 is a top view of an insulating layer 16c of the multilayer substrate 10d. FIG. 15 is a rear view of the multilayer substrate 10d during use.

The multilayer substrate 10d differs from the multilayer substrate 10 in that the columnar conductor v10 is not disposed in at least one of the sections. More specifically, the multilayer substrate 10d includes a third section A3 and fourth sections A4. The third section A3 is bent when viewed in the frontward direction (in the positive direction of a Y axis orthogonal to the Z axis). The columnar conductor v10 (the second columnar conductor) is not disposed in the third section A3. Other components of the multilayer substrate 10d are the same or substantially the same as those of the multilayer substrate 10, and thus are not described. The multilayer substrate 10d can achieve the same or substantially the same advantageous effects as the multilayer substrate 10.

In the multilayer substrate 10d, the columnar conductor v10 is not disposed in the third section A3, and thus the third section A3 can be easily bent.

### Fifth Modified Example

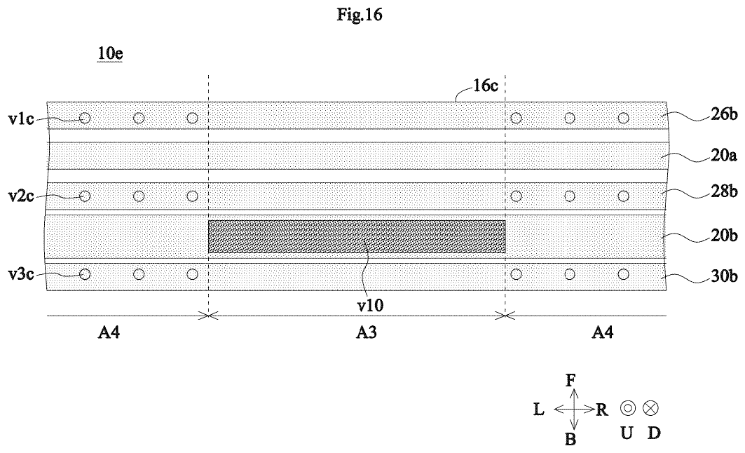

A multilayer substrate 10e according to a fifth modified example embodiment of the present invention is described below with reference to the drawings. FIG. 16 is a top view of an insulating layer 16c of the multilayer substrate 10e. FIG. 15 is to be referred to as a rear view of the multilayer substrate 10e during use.

The multilayer substrate 10e differs from the multilayer substrate 10 in that the columnar conductor v10 is not disposed in at least one of the sections. More specifically, the multilayer substrate 10e includes a third section A3 and fourth sections A4. The third section A3 is bent when viewed in the frontward direction (in the positive direction of the Y axis orthogonal to the Z axis). The columnar conductor v10 (the second columnar conductor) is disposed in the third section A3. Other components of the multilayer substrate 10e are the same or substantially the same as those of the multilayer substrate 10, and thus are not described. The multilayer substrate 10e can achieve the same or substantially the same advantageous effects as the multilayer substrate 10.

In the multilayer substrate 10d, the columnar conductor v10 is disposed in the third section A3. When the third section A3 is bent, the columnar conductor v10 is plastically deformed. Thus, the third section A3 is more easily retained in a bent state.

### Other Example Embodiments

The multilayer substrate according to the present invention is not limited to the multilayer substrates 10, and 10a to 10e, and can be modified within the scope of the present invention. The structures of two or more of the multilayer substrates 10, and 10a to 10e may be combined as appropriate.

The protective layers 18a and 18b are not necessary components.

The first conductor may be a conductive layer.

Multiple small columnar conductors v10 may be arranged along the power-source conductive layer 20b.

The material of the insulating layers 16a to 16d may be ceramics, for example.

The columnar conductor v10 may partially include a section in which its thickness decreases as it extends farther in the upward direction, or the entirety or substantially the entirety of the columnar conductor v10 may have a thickness that decreases as it extends farther in the upward direction.

The material of the multiple columnar conductors v1c, the material of the multiple columnar conductors v2c, and the material of the multiple columnar conductors v3c (the material of the first columnar conductor and the material of the second columnar conductor) may be any suitable material as long as they are the same. Thus, the material of the multiple columnar conductors v1c, the material of the multiple columnar conductors v2c, and the material of the multiple columnar conductors v3c may be different from the material of the signal conductor layer 20a, the material of the power-source conductive layer 20b, the material of the first ground conductive layer 22, the material of the second ground conductive layer 24, the material of the ground conductive layers 26a, 26b, 28a, 28b, 30a, and 30b, the material of the multiple columnar conductors v1d, the material of the multiple columnar conductors v2d, and the material of the multiple columnar conductors v3d.

In FIG. 13, the width of the first section Alb in the direction along the front-rear axis of the multilayer body 12 may be smaller than the width of the first section Ala in the direction along the front-rear axis of the multilayer body 12.

The lower end portion of the columnar conductor v1c may be in contact with the columnar conductor v1d located below the columnar conductor v1c. More specifically, contact is an example of connection.

In the example embodiment illustrated in FIG. 2, the connection conductors v11d to v13d are located in the through-holes provided in the insulating layer 16d, but the connection conductors v11d to v13d may be located in the through-holes provided in the insulating layer 16c. More specifically, the connection conductors may be located at either the destination of connection or the origin of connection.

In the example embodiment illustrated in FIG. 2, the columnar conductors v1c, v2c, and v3c and the columnar conductors v1d, v2d, and v3d are respectively electrically connected with the connection conductors v11d, v12d, and v13d interposed therebetween, but the present invention is not limited to a structure where a connection conductor connects columnar conductors to each other. For example, the columnar conductors v1c, v2c, and v3c may be electrically connected to a conductive layer made from a metal foil such as a copper foil, for example. In this example, the columnar conductors v1c, v2c, and v3c are respectively electrically connected to a conductive layer with the connection conductors v11d, v12d, and v13d interposed therebetween.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate, comprising:
a multilayer body;
a first conductive layer;
a second conductive layer;
a first columnar conductor;
a second columnar conductor; and
a connection conductor; wherein
the multilayer body includes a plurality of insulating layers including a first insulating layer laminated along a Z axis;
the first insulating layer includes a positive main surface and a negative main surface located in a negative direction of the Z axis from the positive main surface;
the first conductive layer and the second conductive layer are provided at the positive main surface of the first insulating layer;
the first columnar conductor and the second columnar conductor are provided in through-holes extending through the first insulating layer along the Z axis;
an end portion of the first columnar conductor in a positive direction of the Z axis is in contact with the first conductive layer;
the connection conductor electrically connects conductors to one another in the lamination direction;
an end portion of the first columnar conductor in the negative direction of the Z axis is connected to a columnar conductor or a conductive layer with the connection conductor;
an end portion of the second columnar conductor in the positive direction of the Z axis is in contact with the second conductive layer;
an end portion of the second columnar conductor in the negative direction of the Z axis is not in contact with any of the conductors;
a material of the first columnar conductor and a material of the second columnar conductor are the same; and
a material of the connection conductor is different from a material of the first and second columnar conductors, and includes a mixture of a resin and a metal, or an alloyed metal.

2. The multilayer substrate according to claim 1, wherein a material of the first columnar conductor and a material of the second columnar conductor are a metal not including a resin.

3. The multilayer substrate according to claim 1, wherein
the first columnar conductor includes a section in which a thickness of the first columnar conductor decreases further as the first columnar conductor extends farther in the positive direction of the Z axis; and
the second columnar conductor includes a section in which a thickness of the second columnar conductor decreases further as the second columnar conductor extends farther in the positive direction of the Z axis.

4. The multilayer substrate according to claim 1, wherein an end surface of the second columnar conductor in the negative direction of the Z axis protrudes in the negative direction of the Z axis.

5. The multilayer substrate according to claim 1, wherein the second conductive layer has a linear shape when viewed in the negative direction of the Z axis.

6. The multilayer substrate according to claim 5, further comprising:
a third columnar conductor; wherein
an end portion of the third columnar conductor in the positive direction of the Z axis is in contact with the second conductive layer;
an end portion of the third columnar conductor in the negative direction of the Z axis is not in contact with any of the conductors;
the second columnar conductor and the third columnar conductor are arranged in a width direction of the second conductive layer when viewed in the negative direction of the Z axis; and
a material of the third columnar conductor is the same as a material of the first columnar conductor.

7. The multilayer substrate according to claim 5, wherein
the multilayer substrate includes a first section in which the second conductive layer has a first width, and a second section in which the second conductive layer has a second width larger than the first width;
the second width is a largest width of the second conductive layer;
the second columnar conductor is provided in the first section; and
the second columnar conductor is not provided in the second section.

8. The multilayer substrate according to claim 5, wherein
the multilayer substrate includes a third section and a fourth section;
the third section is bent when viewed in a positive direction of a Y axis orthogonal or substantially orthogonal the Z axis; and
the second columnar conductor is not provided in the third section.

9. The multilayer substrate according to claim 5, wherein
the multilayer substrate includes a third section and a fourth section;
the third section is bent when viewed in a positive direction of a Y axis orthogonal or substantially orthogonal the Z axis; and
the second columnar conductor is provided in the third section.

10. The multilayer substrate according to claim 1, further comprising:
a third conductive layer; wherein
the third conductive layer is located at the positive main surface of the first insulating layer;
an end portion of a fourth columnar conductor in the positive direction of the Z axis is not connected to the third conductive layer;
the fourth columnar conductor extends through the first insulating layer along the Z axis; and
an end portion of the fourth columnar conductor in the negative direction of the Z axis is not in contact with any of the conductors.

11. The multilayer substrate according to claim 1, wherein
the second conductive layer includes a positive main surface and the negative main surface located in the negative direction of the Z axis from the positive main surface of the second conductive layer; and
a surface roughness of the negative main surface of the second conductive layer is greater than a surface roughness of the positive main surface of the second conductive layer.

12. The multilayer substrate according to claim 1, further comprising a signal conductor layer to which a high-frequency signal with a frequency higher than or equal to about 20 GHz is transmitted.

13. The multilayer substrate according to claim 1, wherein a material of the first conductive layer, a material of the second conductive layer, a material of the first columnar conductor, and a material of the second columnar conductor are the same.

14. A method for manufacturing a multilayer substrate, the method comprising:
preparing a first insulating layer including a positive main surface and a negative main surface located in a negative direction of a Z axis from the positive main surface and a metal foil covering the positive main surface;
forming a first through-hole and a second through-hole extending through the first insulating layer along the Z axis;
forming a first conductive layer and a second conductive layer by processing the metal foil;
forming a first columnar conductor in the first through-hole and forming a second columnar conductor in the second through-hole;
preparing a second insulating layer at which a connection conductor is provided; and
laminating and pressure bonding a plurality of insulating layers including the first insulating layer and the second insulating layer while locating the first insulating layer in a positive direction of the Z axis from the second insulating layer; wherein
an end portion of the first columnar conductor in the positive direction of the Z axis is in contact with the first conductive layer;
an end portion of the second columnar conductor in the positive direction of the Z axis is in contact with the second conductive layer; and
an end portion of the first columnar conductor in the negative direction of the Z axis is connected to the connection conductor.

15. The method for manufacturing a multilayer substrate according to claim 14, wherein the first through-hole and the second through-hole are formed by beam emission or wet-etching.

16. The method for manufacturing a multilayer substrate according to claim 14, wherein a material of the first columnar conductor and a material of the second columnar conductor are a metal not including a resin.

17. The method for manufacturing a multilayer substrate according to claim 14, wherein
the first columnar conductor includes a section in which a thickness of the first columnar conductor decreases further as the first columnar conductor extends farther in the positive direction of the Z axis; and
the second columnar conductor includes a section in which a thickness of the second columnar conductor decreases further as the second columnar conductor extends farther in the positive direction of the Z axis.

18. The method for manufacturing a multilayer substrate according to claim 14, wherein an end surface of the second columnar conductor in the negative direction of the Z axis protrudes in the negative direction of the Z axis.

19. The method for manufacturing a multilayer substrate according to claim 14, wherein the second conductive layer has a linear shape when viewed in the negative direction of the Z axis.

20. The method for manufacturing a multilayer substrate according to claim 14, further comprising:
forming a third columnar conductor; wherein
an end portion of the third columnar conductor in the positive direction of the Z axis is in contact with the second conductive layer;
an end portion of the third columnar conductor in the negative direction of the Z axis is not in contact with any of the conductors;
the second columnar conductor and the third columnar conductor are arranged in a width direction of the second conductive layer when viewed in the negative direction of the Z axis; and
a material of the third columnar conductor is the same as a material of the second columnar conductor.
